(19) United States
(12) Patent Application Publication
(10) Pub. No.: US 2020/0035770 A1
(43) Pub. Date: Jan. 30, 2020

(54) DISPLAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventor: Bo Jiang, Beijing (CN)

(73) Assignee: BOE TECHNOLOGY GROUP CO., LTD., Beijing (CN)

(21) Appl. No.: 16/522,423

(22) Filed: Jul. 25, 2019

(30) Foreign Application Priority Data
Jul. 26, 2018 (CN) 201810836262.X

(51) Int. Cl. H01L 27/32; H01L 51/50; H01L 51/52

(52) U.S. Cl. CPC H01L 27/3246; H01L 2251/5315; H01L 51/5271; H01L 51/502

(57) ABSTRACT

The present disclosure relates to a display substrate and a manufacturing method thereof, and a display device. The display substrate includes a base substrate and a pixel definition layer disposed on the base substrate. The pixel definition layer includes: a plurality of blocking walls defining opening regions; and a reflective layer provided on each blocking wall, the reflective layer covering at least part of surfaces of the blocking wall.

### CROSS-REFERENCE TO RELATED APPLICATION

This application claims priority to Chinese Patent Application No. 201810836262.X filed on Jul. 26, 2018, which is incorporated herein by reference in its entirety.

### TECHNICAL FIELD

The present disclosure relates to the field of display technology, and in particular to a display substrate and a manufacturing method thereof, and a display device.

### BACKGROUND

With the development of display technology, there are more and more types of display devices. Currently, the self-luminescent display devices that are commonly used mainly include: Organic Light-Emitting Diode (OLED) display devices, and Quantum Dot Light-Emitting Diodes (referred to as QLED) display devices. Such display devices have the advantages of wide viewing angle, high contrast and low power consumption in practical applications; however, due to factors such as plasmon loss, substrate absorption, optical waveguide loss, and the like, the above display devices may have a problem of low light extraction efficiency.

### SUMMARY

A first aspect of the present disclosure provides a display substrate which includes a base substrate and a pixel definition layer disposed on the base substrate, the pixel definition layer including:

a plurality of blocking walls defining opening regions; and

a reflective layer provided on each blocking wall, the reflective layer covering at least part of surfaces of the blocking wall.

Optionally, the pixel definition layer further includes a transparent insulation layer covering the reflective layer.

Optionally, the transparent insulation layer is made of a same material as the blocking wall.

Optionally, the reflective layer is made of a metal material.

Optionally, the metal material includes silver or aluminum.

Optionally, a thickness of the reflective layer ranges from 200 to 1000 nm.

Optionally, the reflective layer covers at least a side surface of the blocking wall.

Optionally, the reflective layer covers the blocking wall completely.

Optionally, a cross section of the blocking wall perpendicular to an extending direction of the blocking wall has a trapezoidal or triangular shape.

Based on the technical solution of the above display substrate, a second aspect of the present disclosure provides a display device including the above display substrate.

Based on the technical solution of the above display substrate, a third aspect of the present disclosure provides a manufacturing method of a display substrate, including:

forming a plurality of blocking walls on a base substrate, the blocking walls defining opening regions; and

forming a reflective layer on each blocking wall, the reflective layer covering at least part of surfaces of the blocking wall.

Optionally, the manufacturing method further includes:

forming a transparent insulation layer on the reflective layer, the transparent insulation layer covering the reflective layer completely.

Optionally, the step of manufacturing the plurality of blocking walls on the base substrate includes:

forming a blocking wall thin film on the base substrate; and

patterning the blocking wall thin film using a patterning process to form the plurality of blocking walls.

Optionally, the blocking wall thin film is formed by coating an organic solution including one of polyimide, polymethyl methacrylate or polysiloxane on the base substrate. The step of manufacturing the reflective layer on each blocking wall includes:

depositing the reflective layer on at least part of surfaces of the block wall;

the step of manufacturing the transparent insulation layer on the reflective layer includes:

forming a transparent insulation thin film on the reflective layer; and

patterning the transparent insulation thin film using a patterning process to form the transparent insulation layer.

### BRIEF DESCRIPTION OF THE DRAWINGS

The drawings being a part of the present disclosure are described here to provide a further understanding of the present disclosure. The illustrative embodiments of the present disclosure and the description thereof are for explaining the present disclosure and do not constitute an undue limitation to the present disclosure. In the drawings:

FIG. 1 is a first schematic diagram of a manufacturing process of a display substrate according to an embodiment of the present disclosure;

FIG. 2 is a second schematic diagram of a manufacturing process of a display substrate according to an embodiment of the present disclosure;

FIG. 3 is a third schematic diagram of a manufacturing process of a display substrate according to an embodiment of the present disclosure; and

FIG. 4 is a fourth schematic diagram of a manufacturing process of a display substrate according to an embodiment of the present disclosure.

### DETAILED DESCRIPTION

In order to further explain the display substrate, the manufacturing method thereof and the display device provided by the embodiments of the present disclosure, the following detailed description is made in conjunction with the accompanying drawings.

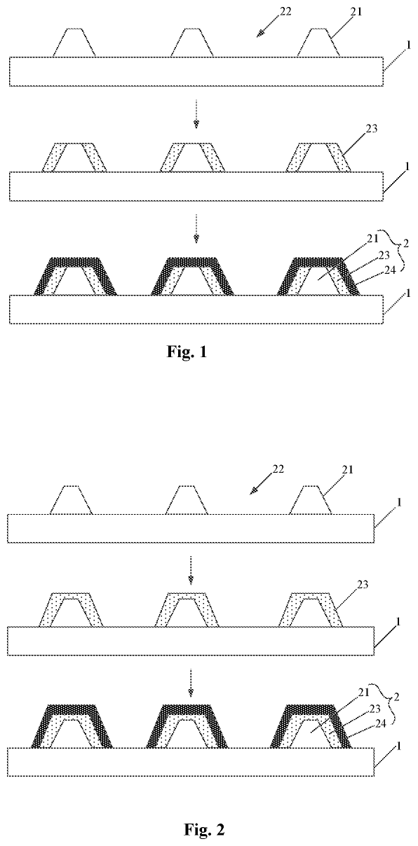

Referring to FIGS. 1 and 2, the display substrate provided by an embodiment of the present disclosure includes a base substrate 1 and a pixel definition layer 2 disposed on the base substrate 1, the pixel definition layer 2 includes: a plurality of blocking walls 21 defining opening regions 22; and a reflective layer 23 provided on the blocking wall 21, the reflective layer 23 covering at least a portion of a region of the blocking wall 21 facing the opening region 22.

An exemplary structure of an OLED display device according to an embodiment of the present disclosure will be described below. The plurality of blocking walls 21 included in the pixel definition layer 2 defines a plurality of opening regions 22 on the base substrate 1. Each opening region 22 corresponds to one pixel unit in the OLED display device. A reflective layer 23 is provided on at least a portion of the region of each blocking wall 21 facing the opening region 22. In each opening region 22, a corresponding anode layer and a light emitting layer are provided sequentially. A cathode layer is provided on each light emitting layer. The light emitting layer can emit various kinds of light under the driving of the anode layer and the cathode layer. The various kinds of light is transmitted inside the display device, reflected by the reflective layers 23, and is finally emitted out of the display device, thus achieving the display function of the OLED display device.

As can be seen from the exemplary structure and the light emitting procedure of the above display substrate, in the display substrate provided by the embodiment of the present disclosure, the reflective layers 23 are formed on the blocking walls 21 for defining the opening regions 22, and each reflective layer 23 covers at least a portion of the region of the blocking wall 21 facing the opening region 22. Here, the “at least a portion of the region of the blocking wall 21 facing the opening region 22” refers to a surface of the blocking wall 21 adjacent to the defined opening region 22, for example, at least a portion of a side surface, or partial surface region of the blocking wall 21 to which the light emitted from the light emitting layer in the opening region 22 can be irradiated. In the case that the display device includes the display substrate provided by the embodiment of the present disclosure, the original transmission path of the light emitted from the light emitting layer in the opening region 22 can be changed under the reflection of the reflective layer 23, so that most of the light can be emitted from the light outgoing side of the display device, thereby improving the light extraction efficiency of the display device, obtaining a larger luminous intensity of the display device under the same power consumption, and effectively overcoming the problem of low light extraction efficiency caused by factors such as plasmon loss, substrate absorption, optical waveguide loss, and the like.

Furthermore, the light emitting layer in the display device may not only emit light under the driving of the anode and the cathode, it may also be excited to emit light when external light is irradiated onto the light emitting layer; however, if the light emitting layer always emits light in an excited state which is abnormal, the service life of the luminescent layer will be affected adversely.

In the display substrate provided in the embodiment of the present disclosure, by providing the reflective layer 23 to cover at least a portion of the region of the blocking wall 21 facing the opening region 22, and causing the light emitted from the light emitting layer in each opening region 22 not to be transmitted into an adjacent pixel unit, the light emitting layers in adjacent pixel units are prevented from being excited by light emitted from each other, which is more advantageous for the service life of the light emitting layers.

In some embodiments, the pixel definition layer 2 provided by the above embodiment further includes: a transparent insulation layer 24 provided on the reflective layer 23, the transparent insulation layer 24 covering the reflective layer 23 completely.

The above reflective layer 23 provided on the blocking wall 21 may be made of various materials, optionally, a conductive material or an insulation material. When the material of the reflective layer 23 is a conductive material, since the reflective may come into contract with an anode layer or a cathode layer included in the display device, it is easy to cause a short circuit between the anode and the cathode in the display device, and the display device is not working properly.

In the display substrate provided by the embodiment of the present disclosure, a transparent insulation layer is provided on the reflective layer 23, and completely covers the reflective layer 23 to completely isolates the reflective layer 23 from the anode layer and the cathode layer in the display device, so as to avoid short circuit between the reflective layer 23 and the anode/cathode layer, and ensures a good performance of the display device.

It should be noted that, the material for forming the above transparent insulation layer 24 is not limited, as long as a good light transmittance and a good insulation property can be provided. Exemplarily, the material of the above transparent insulation layer 24 may be the same as that of the blocking wall 21. In this way, it is ensured that the transparent insulation layer 24 has both light transmissivity and insulation, and the manufacturing process of the display substrate is also simplified.

In some embodiments, the reflective layer 23 provided by the above embodiment may be made of metal material, such as silver, aluminum, and so on. The reflective layer 23 made of metal material not only has a good reflectivity, but also can form a reflective layer 23 having a small thickness, which is more advantageous for thinning of the display device.

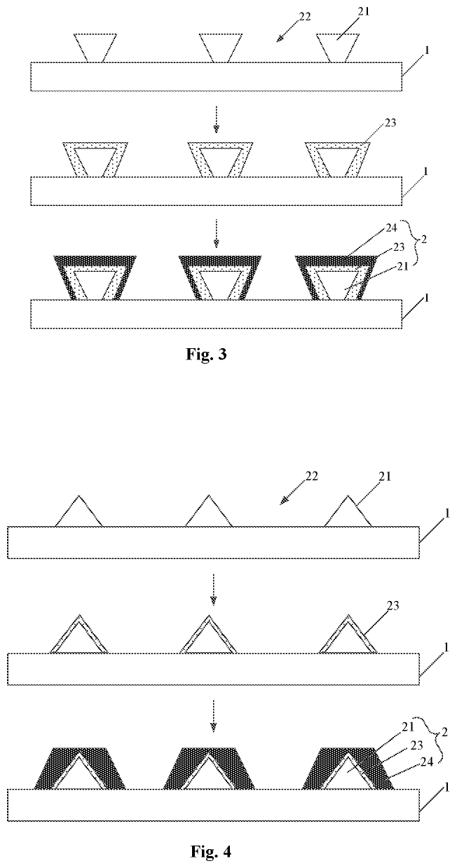

Optionally, in the display substrate provided by the above embodiment, the blocking wall 21 in the pixel definition layer 2 may be configured to have various structures according to actual needs. For example, as shown in FIGS. 2 to 4, a cross section of the blocking wall 21 perpendicular to an extending direction of the blocking wall 21 has a trapezoidal or triangular shape. Obviously, the actual structure of the blocking wall 21 is not limited to above examples.

Specifically, when the cross section of the blocking wall 21 perpendicular to its extending direction has a trapezoidal shape (optionally, including the obverse trapezoid and the inverted trapezoid), for example, assuming that the cross section of the blocking wall 21 perpendicular to its extending direction has a shape of obverse trapezoid, and the reflective layer 23 covers at least the side surface of the blocking wall 21, the light emitted from the light emitting layer can illuminate the display device with a better light extraction efficiency under the reflection of the reflective layer 23. Therefore, for a top-emission type of display device, the blocking wall 21 in the pixel definition layer 2 may be disposed to have an obverse trapezoidal cross section in the direction perpendicular to its extending direction in order to improve the light extraction efficiency of the top-emission type of display device and ensure the light emitting effect.

On the other hand, if the cross section of the blocking wall 21 perpendicular to its extending direction is configured to have a shape of an inverted trapezoid, and the reflective layer 23 covers at least the side surface of the blocking wall 21, the light emitted from the light emitting layer can illuminate the display device with a better light extraction efficiency under the reflection of the reflective layer 23. Therefore, for a bottom-emission type of display device, the blocking wall 21 in the pixel definition layer 2 may be provided with an inverted trapezoidal cross section in the direction perpendicular to its extending direction, such that the light extraction efficiency of the bottom-emission type of display device is improved and the light emitting effect can be ensured.

Furthermore, the cross section of the blocking wall 21 perpendicular to its extending direction may also be configured to have a triangular shape, and the reflective layer 23 covers at least the side surface of the blocking wall 21. Compared with the above blocking wall 21 having an obverse trapezoidal cross section in the direction perpendicular to its extending direction, the reflective layer 23 on the side surface of the blocking wall 21 having a triangular cross section can provide a larger reflection angle when the two types of blocking walls 21 have the same height and the same bottom width. Therefore, the blocking wall 21 having a triangular cross section in the direction perpendicular to its extending direction can further increase the outgoing rays after being reflected by the reflective layer 23, thereby further improving the light extraction efficiency of the display device.

In some embodiments, regardless of the structure of the above blocking wall 21, the reflective layer 23 may be disposed to completely cover the blocking wall 21. Exemplarily, when the cross section of the blocking wall 21 perpendicular to its extending direction has a shape of obverse trapezoid, the reflective layer 23 is disposed to cover the entire region of the blocking wall 21 so that, when light is emitted towards the light outgoing side of the display device, part of the light that is reflected by the substrate on the light outgoing side of the display device is emitted towards the top surface of the blocking wall 21, and reflected back to the substrate on the light outgoing side of the display device by the reflective layer 23 located at the top surface of the blocking wall 21, thus it can be emitted out of the display device from the substrate, thereby further improving the light extraction efficiency of the display device.

It should be noted that, in the case that the cross section of the blocking wall 21 perpendicular to its extending direction has a shape of an inverted trapezoid, and the reflective layer 23 is disposed to cover the entire region of the blocking wall 21, the light extraction efficiency of the display device can also be improved, and a detailed description thereof is not repeated here.

An embodiment of the present disclosure further provides a display device including the display substrate provided in the above embodiments.

Since the display substrate provided by the above embodiment can change the transmission path of the light emitted from the light emitting layer in the opening region 22, most of the light can be emitted from the light outgoing side of the display device, the display device provided by the embodiment of the present disclosure can, when including the display substrate provided by the above embodiment, achieve a better light extraction efficiency, thus improving the light extraction efficiency of the display device, and effectively overcoming the problem of low light extraction efficiency caused by factors such as plasmon loss, substrate absorption, optical waveguide loss, and the like.

In addition, the display device provided by the embodiment of the present disclosure can, when including the display substrate provided by the above embodiment, cause light emitted from the light emitting layers in the opening regions 22 not to be transmitted to an adjacent pixel unit, thus preventing the light emitting layers in adjacent pixel units from being excited by light emitted from each other, which is more advantageous for the service life of the light emitting layers in the display device.

An embodiment of the present disclosure further provides a manufacturing method of a display substrate for manufacturing the display substrate provided by the above embodiment. The manufacturing method includes:

Step 101, forming a plurality of blocking walls 21 on a base substrate 1, the blocking walls 21 defining opening regions 22;

Optionally, the above base substrate 1 may be a base substrate 1 having a driving circuit formed thereon. Exemplarily, a plurality of thin film transistors for driving the display device to emit light is provided in advance on the base substrate 1. A plurality of blocking walls 21 is formed on the base substrate, and a plurality of opening regions 22 are defined on the base substrate 1 by the plurality of blocking walls 21. The opening regions 22 correspond to the pixel units of the display device, and each opening region 22 is provided with a corresponding anode layer and a light emitting layer therein.

Step 102, forming a reflective layer 23 on each blocking wall 21 which covers at least a portion of the region of the blocking wall 21 facing the opening region 22.

Optionally, after the blocking walls 21 have been formed, the reflective layer 23 is formed on at least a part of surface of each blocking wall 21 facing the opening region 22. The reflective layers 23 are used to change the transmission path of light emitted from the light emitting layers in the opening regions 22 so that more light emitted from the light emitting layers is output from the light outgoing side of the display device.

In the display substrate manufactured by the manufacturing method provided by the above embodiment, a reflective layer 23 is formed on each blocking wall 21 for defining the opening region 22, and the reflective layer 23 can cover at least a portion of the region of the blocking wall 21 facing the opening region 22. In the case that the display device includes the display substrate manufactured by the manufacturing method provided by the embodiment of the present disclosure, the original transmission path of the light emitted from the light emitting layer in the opening region 22 can be changed under the reflection of the reflective layer 23, so that most of the light can be emitted from the light outgoing side of the display device, thereby improving the light extraction efficiency of the display device, and effectively overcoming the problem of low light extraction efficiency caused by factors such as plasmon loss, substrate absorption, optical waveguide loss, and the like.

In addition, in the case that the display device includes the display substrate manufactured by the manufacturing method provided by the embodiment of the present disclosure, the reflective layers 23 provided in the display substrate can cover at least part of the regions of the blocking walls 21 facing the opening regions 22, so that light emitted from the light emitting layers in the opening regions 22 is not transmitted to an adjacent pixel unit, thus preventing the light emitting layers in adjacent pixel units from being excited by light emitted from each other, which is more advantageous for the service life of the light emitting layers.

Optionally, the manufacturing method of a display substrate provided by the above embodiment further includes:

Step 103, forming a transparent insulation layer 24 on the reflective layer 23, the transparent insulation layer 24 covering the reflective layer 23 completely.

Optionally, since the reflective layer 23 covers at least a portion of the region of the blocking wall 21 facing the opening region 22, in order to prevent the reflective layer 23 from affecting the light emitting layer in the opening region 22, and prevent the reflective layer 23 from short-circuiting the anode layer and the cathode layer in the display device when the reflective layer 23 is made of a metal material, the transparent insulation layer 24 covering the reflective layer 23 completely is subsequently formed on the reflective layer 23 after the reflective layer 23 has been formed, so that the reflective layer 23 is completely separated from the light emitting layer, the anode layer and the cathode layer in the display device by the transparent insulating layer 24, thereby ensuring a normal display function of the display device.

In some embodiments, the above step 101 of manufacturing the plurality of blocking walls 21 on the base substrate 1 includes:

forming a blocking wall thin film on the base substrate 1; and

patterning the blocking wall thin film using a patterning process to form the plurality of blocking walls 21.

The blocking wall thin film may be formed by various methods. Exemplarily, a layer of the blocking wall thin film may be coated on the base substrate 1 by spin coating, inkjet printing, or the like using an organic solution such as polyimide, polymethyl methacrylate or polysiloxane; then, the blocking wall thin film is exposed to form a blocking wall thin film removing region and a blocking wall thin film retaining region, and then the exposed blocking wall thin film is developed by using a developing solution to remove the organic material located in the blocking wall thin film removing region; after the development, remaining blocking wall thin films which are located in the blocking wall thin film retaining region are the plurality of blocking walls 21 to be formed on the substrate 1. It should be noted that, in addition to the above organic solution, an inorganic material may also be adopted to manufacture the blocking wall thin film, by using, for example but not limited to, chemical vapor deposition method.

It should be noted that, a thickness of the above blocking wall 21 in a direction perpendicular to the base substrate 1 may be set according to an actual need, for example, from 1 μm to 3 μm. In addition, the cross section of the above blocking wall perpendicular to its extending direction may, for example, have a shape of obverse trapezoid, inverted trapezoid, or triangle.

The above step 102 of manufacturing the reflective layer 23 on each blocking wall 21 includes: depositing the reflective layer 23 on at least a portion of the region of the block wall 21 facing the opening region 22;

The reflective layer 23 may be made of various materials, for example, a metal material. Silver, aluminum, and so on may be selected as the metal material to manufacture the reflective layer 23. The reflective layer 23 made of silver or aluminum not only has a good reflectivity, but also can form a thinner reflective layer 23, which is more advantageous for thinning of the display device. When manufacturing the reflective layer 23, a manufacturing process such as a vapor deposition or a magnetron sputtering may be employed, and the thickness of the reflective layer 23 in the direction perpendicular to the base substrate 1 may be set depending upon practical requirements. For example, the thickness may range from 30 nm to 5000 nm, and optionally range from 200 nm to 1000 nm.

The above step 103 of forming the transparent insulation layer 24 on the reflective layer 23 includes:

forming a transparent insulation thin film on the reflective layer 23; and

patterning the transparent insulation thin film using a patterning process to form the transparent insulation layer 24.

The transparent insulation layer 24 may be made of various materials as long as thus formed transparent insulation layer 24 has a good light transmittance and a good insulation property. Exemplarily, the transparent insulation layer 24 may be made of the material for manufacturing the above blocking wall 21. Specifically, when the organic solution for manufacturing the above blocking wall 21 is selected to manufacture the transparent insulation layer 24, a layer of transparent insulation thin film may be coated on the reflective layer 23 using the above organic solution; then, the transparent insulation thin film is exposed to form a transparent insulation thin film removing region and a transparent insulation thin film retaining region, and then the exposed transparent insulation thin film is developed by using a developing solution to remove the organic material located in the transparent insulation thin film removing region; after the development, remaining transparent insulation thin film which is located in the transparent insulation thin film retaining region is the transparent insulation layer 24 to be formed on the reflective layer 23.

It should be noted that, the above transparent insulation layer 24, the reflective layer 23 and the blocking wall 21 together constitute the pixel definition layer 2 provided by the embodiment of the present disclosure. Optionally, a cross section of the pixel definition layer 2 perpendicular to its extending direction may have a shape of obverse trapezoid or an inverted trapezoid. Furthermore, the thickness of the above transparent insulation layer 24 in the direction perpendicular to the base substrate 1 may be set according to an actual need, for example, from 1.5 μm to 3 μm. The total thickness of the above pixel definition layer 2 may be set to 1 μm to 6 μm.

The various embodiments in the specification are described in a progressive manner, and the same or similar parts between the various embodiments may be referred to each other, and the description for each embodiment focuses on the differences from other embodiments. In particular, for the method embodiment, since it is substantially similar to the product embodiment, the description is relatively simple, and the relevant parts can be referred to the description of the product embodiment.

Unless defined otherwise, all technical and scientific terms used herein have the same meaning as commonly understood by one of ordinary skill in the art to which this invention belongs. The words “first”, “second”, and similar terms used in the present disclosure do not denote any order, quantity, or importance, but are used to distinguish different components. The word “comprise” or “include” or the like means that the element or item preceding the word covers the element(s) or item(s) listed after the word, and other element(s) or item(s) is/are not excluded. The word “connecting” or “connected” or the like are not limited to physical or mechanical connections, but may include electrical connections, whether direct or indirect. “Upper”, “lower”, “left”, “right”, etc. are only used to indicate the relative positional relationship, and when the absolute position of the object to be described is changed, the relative positional relationship may also be changed accordingly.

It will be appreciated that, when an element such as a layer, a film, a region or a substrate is referred to as being “on” or “under” another element, the element may be directly “on” or “under” the other element, or there may be intermediate element(s).

In the description of the above embodiments, specific features, structures, materials or characteristics may be combined in any suitable manner in any one or more implementations or examples.

The above is only the specific implementations of the present disclosure, but the protective scope of the present disclosure is not limited thereto, and any changes or substitutions that are obvious to those skilled in the art within the scope of the present disclosure are intended to be included within the protective scope of the present disclosure. Therefore, the protective scope the present disclosure should be determined by the scope of the appended claims.

What is claimed is:

1. A display substrate, comprising a base substrate and a pixel definition layer disposed on the base substrate, the pixel definition layer comprising:
a plurality of blocking walls defining opening regions; and
a reflective layer provided on each blocking wall, the reflective layer covering at least part of surfaces of the blocking wall.

2. The display substrate according to claim 1, wherein the pixel definition layer further comprises a transparent insulation layer covering the reflective layer.

3. The display substrate according to claim 2, wherein the transparent insulation layer is made of a same material as the blocking wall.

4. The display substrate according to claim 1, wherein the reflective layer is made of a metal material.

5. The display substrate according to claim 4, wherein the metal material comprises silver or aluminum.

6. The display substrate according to claim 5, wherein a thickness of the reflective layer ranges from 200 to 1000 nm.

7. The display substrate according to claim 1, wherein the reflective layer covers at least a side surface of the blocking wall.

8. The display substrate according to claim 7, wherein the reflective layer covers the blocking wall completely.

9. The display substrate according to claim 1, wherein a cross section of the blocking wall perpendicular to an extending direction of the blocking wall has a trapezoidal or triangular shape.

10. A display device comprising the display substrate according to claim 1.

11. A manufacturing method of a display substrate, comprising:
forming a plurality of blocking walls on a base substrate, the blocking walls defining opening regions; and
forming a reflective layer on each blocking wall, the reflective layer covering at least part of surfaces of the blocking wall.

12. The manufacturing method according to claim 11, further comprising:
forming a transparent insulation layer on the reflective layer, the transparent insulation layer covering the reflective layer completely.

13. The manufacturing method according to claim 11, wherein the step of forming the plurality of blocking walls on the base substrate comprises:
forming a blocking wall thin film on the base substrate; and
patterning the blocking wall thin film using a patterning process to form the plurality of blocking walls.

14. The manufacturing method according to claim 13, wherein the blocking wall thin film is formed by coating an organic solution of one of polyimide, polymethyl methacrylate or polysiloxane on the base substrate.

15. The manufacturing method of a display substrate according to claim 11, wherein the step of forming the reflective layer on each blocking wall comprises:
depositing the reflective layer on at least part of surfaces of the block wall.

16. The manufacturing method according to claim 12, wherein the step of forming the transparent insulation layer on the reflective layer comprises:
forming a transparent insulation thin film on the reflective layer; and
patterning the transparent insulation thin film using a patterning process to form the transparent insulation layer.
